(19) United States
(12) Patent Application Publication
(10) Pub. No.: US 2025/0323187 A1
(43) Pub. Date: Oct. 16, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Nian-Ting Jung, Kaohsiung City (TW); Ming-Chyi Liu, Hsinchu City (TW); Yi-Han Liao, Taichung City (TW)

(73) Assignee: Taiwan Semiconductor Manufacturing Company, Ltd., Hsinchu (TW)

(21) Appl. No.: 18/633,541

(22) Filed: Apr. 12, 2024

(51) Int. Cl. H01L 23/00

(52) U.S. Cl. CPC H01L 24/05; H01L 24/03; H01L 24/08; H01L 2224/03462; H01L 2224/03622; H01L 2224/05009; H01L 2224/08146

(57) ABSTRACT

A semiconductor device includes a first dielectric layer, a second dielectric layer, a first conductive layer and a second conductive layer. The second dielectric layer is disposed on the first dielectric layer. The first dielectric layer and the second dielectric layer are respectively a single layer. The first conductive layer is disposed in the first dielectric layer and the second dielectric layer. The first conductive layer substantially has a first width in the first dielectric layer and the second dielectric layer. The second conductive layer is disposed in the second dielectric layer. The second conductive layer has a second width larger than the first width and is disposed over the first conductive layer.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), and package on package (POP) devices. Some 3DICs are prepared by placing chips over chips on a semiconductor wafer level. The 3DICs provide improved integration density and other advantages, such as faster speeds and higher bandwidth, because of the decreased length of interconnects between the stacked chips. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1I are schematic cross-sectional views of various stages in a method of forming a semiconductor device according to some embodiments.

FIG. 2 is a schematic cross-sectional view of a semiconductor device according to some embodiments.

FIG. 3 is a schematic cross-sectional view of a semiconductor device according to some embodiments.

FIG. 4 is a schematic cross-sectional view of a semiconductor device according to some embodiments.

FIG. 5 illustrates a flowchart of a method of forming a semiconductor device according to some embodiments.

FIG. 6 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

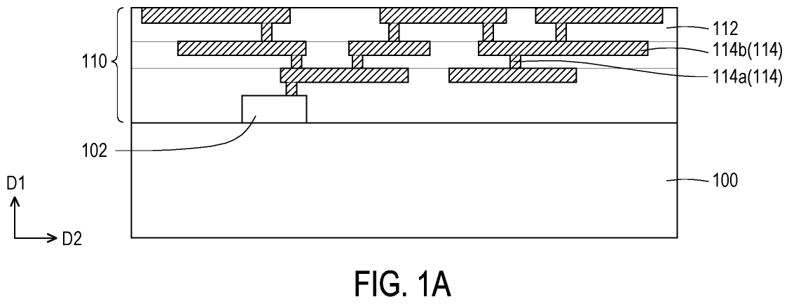

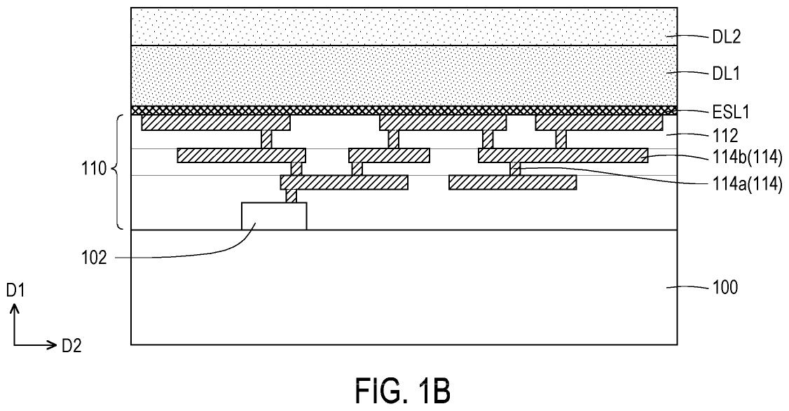

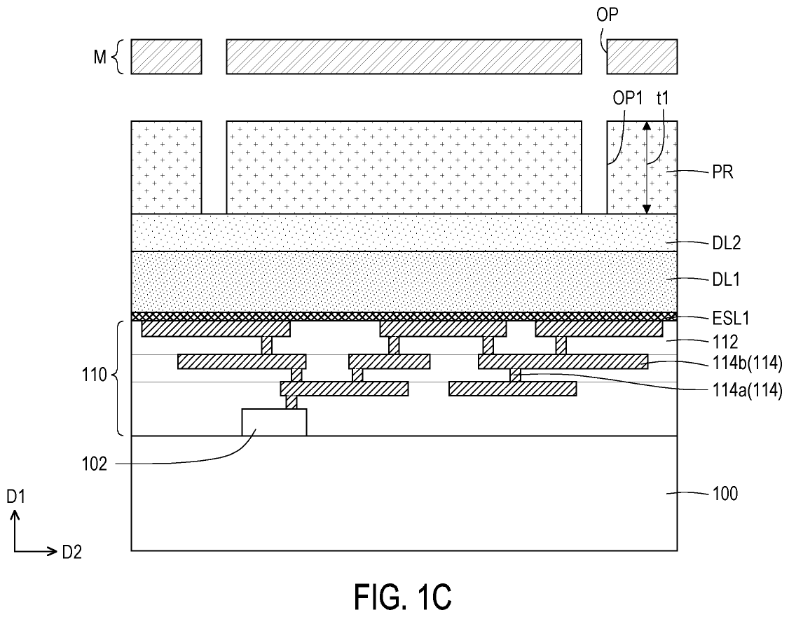

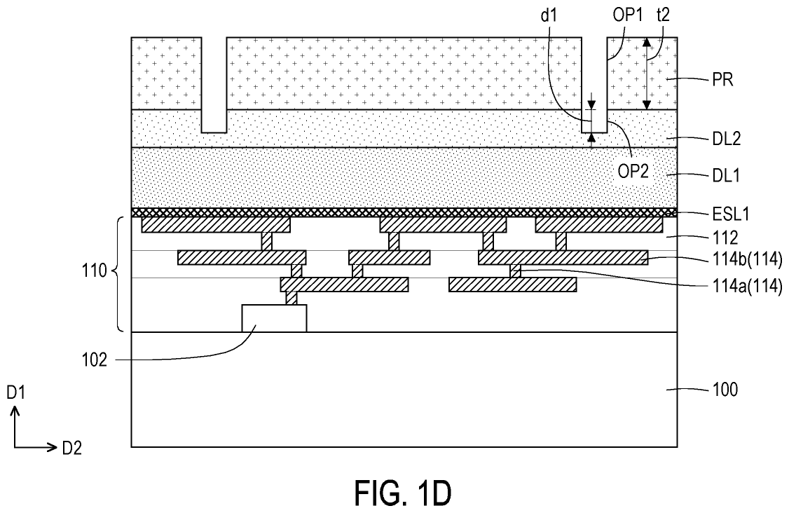

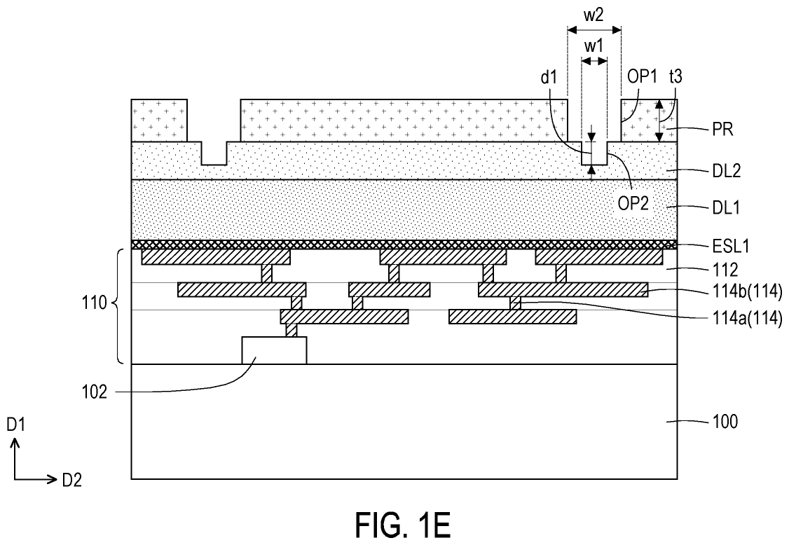

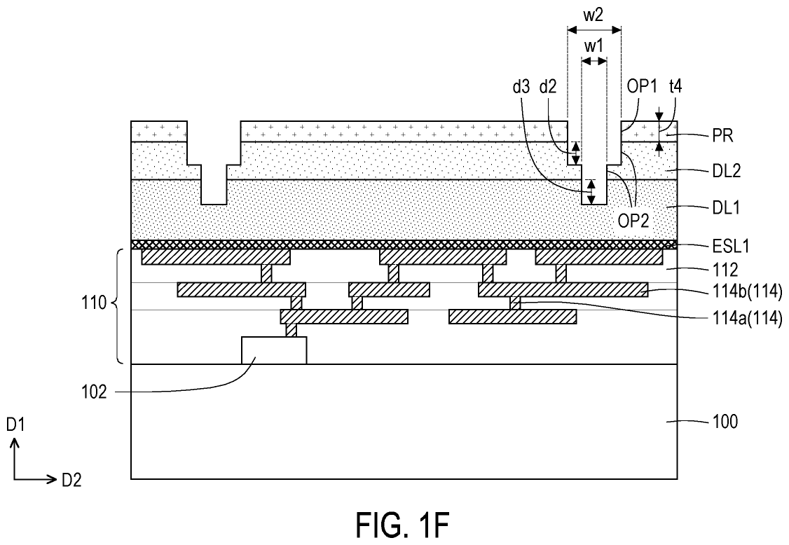

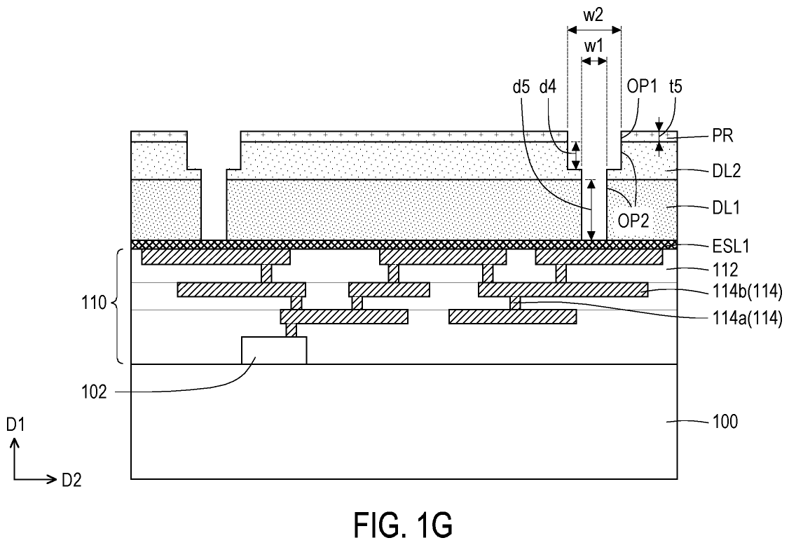

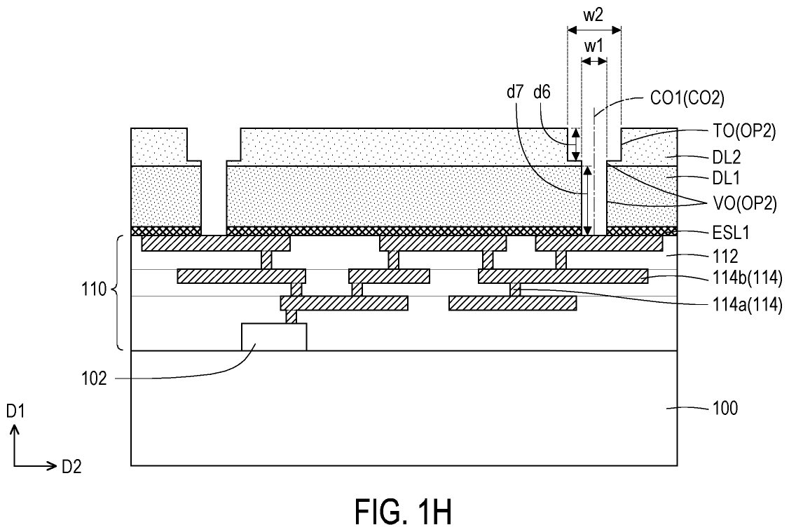

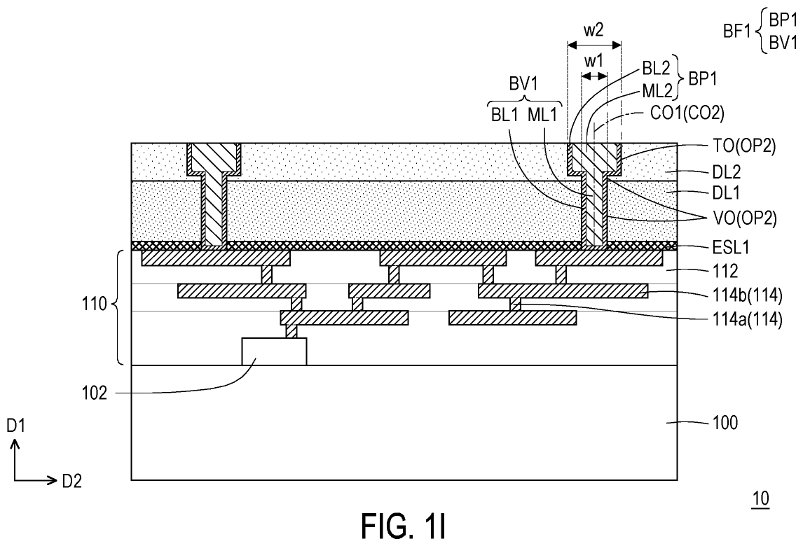

FIG. 1A to FIG. 1I are schematic cross-sectional views of various stages in a method of forming a semiconductor device according to some embodiments.

Referring to FIG. 1A, a substrate 100 is provided, and an interconnect structure 110 is formed over the substrate 100. The substrate 100 includes an elementary semiconductor such as silicon, germanium and/or a compound semiconductor such as silicon germanium, silicon carbide, gallium arsenic, indium arsenide, gallium nitride or indium phosphide. In some embodiments, the substrate 100 includes a silicon-containing material. For example, the substrate 100 is a silicon-on-insulator (SOI) substrate or a silicon substrate. The silicon substrate includes a single-crystalline silicon substrate, an amorphous silicon substrate, a polysilicon substrate or a combination thereof. In various embodiments, the substrate 100 may take the form of a planar substrate, a substrate with multiple fins, nanowires, or other forms known to people having ordinary skill in the art. Depending on the requirements of design, the substrate 100 may be a P-type substrate or an N-type substrate and may have doped regions therein. The doped regions may be configured for an N-type device or a P-type device. In some embodiments, the substrate 100 may have through substrate vias (not shown) therein upon the process requirements.

The substrate 100 includes isolation structures defining at least one active area, and at least one device 102 is disposed in the active area. The at least one device 102 includes one or more functional devices. In some embodiments, the functional devices include active components, passive components, or a combination thereof. In some embodiments, the functional devices may include integrated circuits devices. The functional devices are, for example, transistors, capacitors, resistors, diodes, photodiodes, fuse devices and/or other similar devices. In some embodiments, the device 102 includes a gate dielectric layer, a gate electrode, source/drain regions, spacers, and the like.

The interconnect structure 110 is disposed over a first side (e.g., front side) of the substrate 100 along a first direction D1. The first direction D1 is, for example, a vertical direction such as z direction. In some embodiments, a second direction D2 us substantially perpendicular to the first direction D1. The second direction D2 is, for example, a horizontal direction such as x direction or y direction. The width w1 corresponds to a width of a via opening to be formed. Specifically, the interconnect structure 110 is disposed over and electrically connected to the device 102. In some embodiments, the interconnect structure 110 includes a plurality of dielectric layers 112 and conductive features 114 in the dielectric layers 112. The conductive features 114 are disposed in the dielectric layers 112 and electrically connected with each other. Portions of the conductive features 114 are exposed by the topmost dielectric layer 112. In some embodiments, the dielectric layer 112 is a single layer or a multilayer structure, and includes silicon oxide, silicon oxynitride, silicon nitride, a low dielectric constant (low-k) material having a dielectric constant less than 3.5, or a combination thereof. In some embodiments, the conductive features 114 include conductive vias 114a and conductive lines 114b. The conductive vias 114a may include contacts formed in the inter-layer dielectric layer, and vias formed in the inter-metal dielectric layer. The contacts are formed between and in contact with a bottom conductive line and the underlying device 102, for example. The vias are formed between and in contact with two conductive lines, for example. Each conductive feature 114 may include tungsten (W), copper (Cu), a copper alloy, aluminum (Al), an aluminum alloy or a combination thereof. In some embodiments, a barrier layer may be disposed between each conductive feature 114 and the dielectric layer 112 to prevent the material of the conductive feature 114 from migrating to the underlying device 102. The barrier layer may include Ta, TaN, Ti, TiN, CoW or a combination thereof. A seed layer may be optionally formed between each conductive feature and the barrier layer. The seed layer may include Cu, Ag or the like. In some embodiments, the interconnect structure 110 further includes an etching stop layer between two adjacent conductive features and/or two adjacent dielectric layers. The etching stop layer may include SiN, SiC, SiCN, AlN, Al₂O₃ or a combination thereof. In some embodiments, the interconnect structure 110 is formed by a dual damascene process. In alternative embodiments, the interconnect structure 110 is formed by multiple single damascene processes. In yet alternative embodiments, the interconnect structure 110 is formed by an electroplating process.

Referring to FIG. 1B, a first dielectric layer DL1 is formed over the interconnect structure 110, and a second dielectric layer DL2 is formed on the first dielectric layer DL1. For example, a first etching stop layer ESL1 is formed on the topmost dielectric layer 112 of the interconnect structure 110 along the first direction D1, and the first dielectric layer DL1 and the second dielectric layer DL2 are sequentially formed on the first etching stop layer ESL1 along the first direction D1. In some embodiments, each of the first dielectric layer DL1 and the second dielectric layer DL2 include silicon oxide, silicon oxynitride, silicon nitride, a low dielectric constant (low-k) material having a dielectric constant less than 3.5, or a combination thereof. In some embodiments, the first dielectric layer DL1 and the second dielectric layer DL2 include different materials. For example, the first dielectric layer DL1 includes high density plasma (HDP) oxide material, and the second dielectric layer DL2 includes silicon oxynitride. In some embodiments, the etching stop layer EL1 may include SiN, SiC, SiCN, AlN, Al₂O₃ or a combination thereof. The thickness of the first dielectric layer DL1 may be larger than, substantially equal to or smaller than the thickness of the second dielectric layer DL2. In some embodiments, the first dielectric layer DL1 has a thickness ranging from 2 μm to 4 μm, and the second dielectric layer DL2 has a thickness ranging from 2 μm to 4 μm. The etching stop layer ESL1 may have a thickness ranging from 0.4 μm to 0.7 um. However, the disclosure is not limited thereto. The first dielectric layer DL1, the second dielectric layer DL2 and the etching stop layer ESL1 may have any suitable thickness.

Referring to FIG. 1C, by using a mask M, a photoresist layer PR having a first opening OP1 is formed on the second dielectric layer DL2. The mask M includes a plurality of openings OP. For example, a photoresist material (not shown) is formed on the second dielectric layer DL2 by a spin coating or the like. The photoresist material may be a positive photosensitive material and includes organic materials. Then, by using the mask M, the photoresist material is exposed to light for patterning, to form the photoresist layer PR having the first opening OP1. In some embodiments, the first opening OP1 has a width w1 along the second direction D2. The width w1 corresponds to a width of a via opening to be formed. In some embodiments, the photoresist layer PR has a thickness t1 based on a width and a depth of a trench opening and a via opening to be formed. The thickness t1 may be in a range of 5 μm to 10 μm. For example, a thickness of the photoresist layer PR is substantially equal to a total thickness of the first dielectric layer DL1, the second dielectric layer DL2 and the etching stop layer ESL1. However, the disclosure is not limited thereto.

Referring to FIG. 1D, by using the photoresist layer PR having the first opening OP1 as a mask, a second opening OP2 is formed in the second dielectric layer DL2. The opening OP2 may be formed by removing a portion of the second dielectric layer DL2. The removal method may include an etch process such as a dry etch process or a wet etch process. During the partial removal of the second dielectric layer DL2, the photoresist layer PR may be also partially removed. For example, the thickness t1 of the photoresist layer PR is reduced to a thickness t2 while the width w1 of the first opening OP1 is retained. In some embodiments, the second opening OP2 has a width substantially the same as the width w1 of the first opening OP1 along the second direction D2 and a depth d1 along the first direction D1. The depth d1 is smaller than a thickness of the second dielectric layer DL2. That is, the second opening OP2 does not penetrate through an entirety of the second dielectric layer DL2. In some embodiments, the process (e.g., breakthrough process) is performed under a pressure in a range of 20 mTorr to 50 mTorr, a source power in a range of 2000 W to 4000 W, a bias power in a range of 1000 W to 3000 W, gases including Ar in a range of 500 sccm to 1500 sccm, O₂ in a range of 0 sccm to 200 sccm and CHF₃ in a range of 0 sccm to 200 sccm. However, the disclosure is not limited thereto. The process may be performed by using any suitable process parameters.

Referring to FIG. 1E, the first opening OP1 of the photoresist layer PR is extended. In some embodiments, the first opening OP1 of the photoresist layer PR is extended by using a pull-back process. The pull-back process provides an isotropic etching process by reducing vertical bias, so that an etch rate of the pull-back process in the first direction D1 (e.g., vertical direction) may be lowered. For example, a bias power of the vertical bias is in a range of 0 to 1500 w. However, the disclosure is not limited thereto. The process may be performed by using any suitable process parameters. In some embodiments, as shown in FIG. 1D and FIG. 1E, the width w1 of the first opening OP1 of the photoresist layer PR is increased to the width w2 while the thickness t2 of the photoresist layer PR is decreased to the thickness t3. The width w2 corresponds to a width of a trench opening to be formed. In some embodiments, the pull-back process is also referred to as a photoresist stripping process or an in-situ pull-back process.

Referring to FIG. 1F, the second opening OP2 is expanded in the second dielectric layer DL2 and extended into the first dielectric layer DL1. In some embodiments, by using the photoresist layer PR having the first opening OP1 with the width w2 as a mask, a portion of the second opening OP2 in the second dielectric layer DL2 has the width w2, and a portion of the second opening OP2 extended into the first dielectric layer DL1 has the width w1. The opening OP2 may be expanded and extended by removing portions of the first and second dielectric layers DL1 and DL2. The removal method may include an etch process such as a dry etch process or a wet etch process. During the partial removal of the first and second dielectric layers DL1 and DL2, the photoresist layer PR may be also partially removed. For example, the thickness t3 of the photoresist layer PR is reduced to the thickness t4 while the width w2 of the first opening OP1 is retained. In some embodiments, the second opening OP2 having the width w2 has a depth d2 in the second dielectric layer DL2, and the second opening OP2 having the width w1 has a depth d3 in the first dielectric layer DL1. The depth d2 is smaller than the depth d1 of FIG. 1E, for example. The depth d3 is smaller than a thickness of the first dielectric layer DL1. That is, the second opening OP2 does not penetrate through an entirety of the first dielectric layer DL1. In some embodiments, the process (e.g., breakthrough process) is performed under a pressure in a range of 20 mTorr to 50 mTorr, a source power in a range of 2000 W to 4000 W, a bias power in a range of 1000 W to 3000 W, gases including Ar in a range of 500 sccm to 1500 sccm, O₂ in a range of 0 sccm to 200 sccm and CHF₃ in a range of 0 sccm to 200 sccm. The process parameters of FIG. 1F may be similar to or substantially the same as that of the process of FIG. However, the disclosure is not limited thereto. The process may be performed by using any suitable process parameters.

Referring to FIG. 1G, the second opening OP2 is further extended in the second dielectric layer DL2 and in the first dielectric layer DL1. In some embodiments, by using the photoresist layer PR having the first opening OP1 with the width w2 as a mask, the depth d2 of the second opening OP2 having the width w2 is increased to depth d4, and the depth d3 of the second opening OP2 having the width w1 is increased to depth d5. That is, the second opening OP2 is deepened into both first and second dielectric layers DL1 and DL2. The opening OP2 may be deepened by removing portions of the first and second dielectric layers DL1 and DL2. The removal method may include an etch process such as a dry etch process or a wet etch process. During the partial removal of the first and second dielectric layers DL1 and DL2, the photoresist layer PR may be also partially removed. For example, the thickness t4 of the photoresist layer PR is reduced to the thickness t5 while the width w2 of the first opening OP1 is retained. In some embodiments, the second opening OP2 having the width w2 has the depth d4 in the second dielectric layer DL2, and the second opening OP2 having the width w1 has the depth d5 in the first dielectric layer DL1. The depth d4 is smaller than a thickness of the second dielectric layer DL2 and the depth d5 is substantially equal to a thickness of the first dielectric layer DL1. That is, the second opening OP2 having the width w2 does not penetrate through an entirety of the second dielectric layer DL2 while the second opening OP2 having the width w1 penetrates through an entirety of the first dielectric layer DL1. That is, the second opening OP2 has the width w1 throughout the first dielectric layer DL1, for example. In some embodiments, the etching uniformity is improved by adjusting the process parameters, so that the formed second opening OP2 having the width w2 do not penetrate through an entirety of the second dielectric layer DL2. Furthermore, the etching process is also controlled to prevent the underlying etching stop layer ESL1 from being etched. In some embodiments, the etching rate of the process of FIG. 1G is smaller than the etching rate of the process of FIG. 1D and/or FIG. 1F. For example, the process is performed under a pressure in a range of 20 mTorr to 50 mTorr, a source power in a range of 500 W to 2000 W, a bias power in a range of 500 W to 2500 W, gases including Ar in a range of 500 sccm to 1500 sccm, O₂ in a range of 0 sccm to 200 sccm, CHF₃ in a range of 0 sccm to 200 sccm and C₅F₈ in a range of 0 sccm to 200 sccm. However, the disclosure is not limited thereto. The process may be performed by using any suitable process parameters.

Referring to FIG. 1H, the remaining photoresist layer PR is removed. The removal process may be an acceptable ashing or stripping process, such as using an oxygen plasma or the like. In some embodiments, the process is performed under a pressure in a range of 200 mTorr to 1500 mTorr, a source power in a range of 1000 W to 3000 W, a bias power in a range of 200 W to 1500 W and a gas including O₂ in a range of 500 sccm to 2500 sccm. However, the disclosure is not limited thereto. The process may be performed by using any suitable process parameters. In some embodiments, the photoresist layer PR is completely removed.

After removal of the remaining photoresist layer PR, a portion of the second dielectric layer DL2 and a portion of the etching stop layer ESL1 may be also removed. In some embodiments, the etching process to the etching stop layer ESL1 is performed after the removal of the photoresist layer PR. Thus, the oxygen used in the removal of the photoresist layer P may be prevented from being in contact with the underlying conductive feature such as conductive feature 114. In some embodiments, the etching uniformity is improved by adjusting the process parameters, and the second opening OP2 having the width w2 is controlled to not to penetrate through an entirety of the second dielectric layer DL2. For example, the process is performed under a pressure in a range of 50 mTorr to 1000 mTorr, a source power in a range of 200 W to 2000 W, a bias power in a range of 150 W to 1500 W and gases including N₂ in a range of 150 sccm to 1000 sccm and CF₄ in a range of 0 sccm to 250 sccm. However, the disclosure is not limited thereto. The process may be performed by using any suitable process parameters. In some embodiments, the depth d4 of the second opening OP2 having the width w2 is increased to depth d6, and the depth d5 of the second opening OP2 having the width w1 is increased to depth d7 and may penetrate through etching stop layer ESL1. For example, the depth d6 of the second opening OP2 having the width w2 is smaller than the thickness of the second dielectric layer DL2. The depth d7 of the second opening OP2 having the width w1 may be substantially equal to a total of the thickness of the first dielectric layer DL and the thickness of the etching stop layer ESL1. In some embodiments, the second opening OP2 having the width w2 (also referred to as trench opening TO) is disposed in the second dielectric layer DL2 while the second opening OP2 having the width w1 (also referred to as via opening VO) is disposed in the second dielectric layer DL2, the first dielectric layer DL1 and the etching stop layer ESL1. For example, the trench opening TO penetrates through a portion (e.g., upper portion) of the second dielectric layer DL2 while the via opening VO penetrates through another portion (e.g., lower portion) of the second dielectric layer DL2, an entirety of the first dielectric layer DL1 and an entirety of the etching stop layer ESL1.

The trench opening TO is disposed on the via opening VO and communicated with the via opening VO. As shown in FIG. 1H, a central axis CO1 of the via opening VO is substantially overlapped with a central axis CO2 of the trench opening TO, for example. That is, the via opening VO and the trench opening TO may be coaxial and thus have coaxial profiles. For example, the second opening OP2 including the via opening VO and the trench opening TO has a ladder-shaped profile. In some embodiments, the via opening VO may expose the underlying conductive feature such as topmost conductive feature 114 of the interconnect structure 110. In an embodiment (not shown) in which the via opening and the trench opening are formed by using a dual-damascene process, there may be overlay concern and cost concern due to the use of two masks (e.g., one for forming the via opening and one for forming the trench opening). On contrary, in some embodiment, by using the pull-back process to the photoresist layer, the via opening and the trench opening may be formed by using only one mask (e.g., mask for defining the width of the via opening), and thus the overlay concern is avoided and/or the cost may be lowered. In addition, there is no needed to form a photoresist plug. Furthermore, the conversion gain may be improved.

Referring to FIG. 1I, a bonding feature BF1 is formed in the second opening OP2 in the first and second dielectric layers DL1 and DL2. In some embodiments, the bonding feature BF1 includes a bonding via BV1 in the via opening VO and an overlying bonding pad BP1 in the trench opening TO. The bonding via BV1 is continuously disposed in the second dielectric layer DL2, the first dielectric layer DL1 and the etching stop layer ESL1, and the bonding pad BP1 is continuously disposed in the second dielectric layer DL2 and the first dielectric layer DL1, for example. The bonding pad BP1 is disposed over (e.g., in physical contact with) the bonding via BV1 and are integrated formed, for example. The bonding via BV1 and the bonding pad BP1 may respectively include conductive layers ML1, ML2, and the conductive layer ML1, ML2 may include tungsten (W), copper (Cu), a copper alloy, aluminum (Al), an aluminum alloy or a combination thereof. The conductive layer ML1 is continuously disposed in the first dielectric layer DL1, the second dielectric layer DL2 and the etching stop layer ESL1, for example. The conductive layer ML1 and the conductive layer ML2 may be integrally formed. That is, no interface exists between the conductive layer ML1 and the conductive layer ML2. In some embodiments, a barrier layer BL1, BL2 is formed between the conductive layer ML1, ML2 and the dielectric layers DL1 and DL2 and the etching stop layer ESL1 to prevent the material of the bonding feature BF1 from migrating to the underlying device 102. The barrier layer BL1, BL2 may include Ta, TaN, Ti, TiN, CoW or a combination thereof. The barrier layer BL1 is continuously disposed in the first dielectric layer DL1, the second dielectric layer DL2 and the etching stop layer ESL1, for example. The barrier layer BL1 and the barrier layer BL2 may be integrally formed. That is, no interface exists between the barrier layer BL1 and the barrier layer BL2. A seed layer (not shown) may be optionally formed between each bonding feature BF1 and the barrier layer BL1, BL2. The seed layer may include Cu, Ag or the like.

In some embodiments, the bonding via BV1 includes the conductive layer ML1 and the barrier layer BL1 surrounding the conductive layer ML1 and the bonding pad BP1 includes the conductive layer ML2 and the barrier layer BL2 surrounding the conductive layer ML2. In some embodiments, a surface (e.g., top surface) of the bonding feature BF1 is substantially coplanar with a surface (e.g., top surface) of the second dielectric layer DL2 and a surface (e.g., bottom surface) of the bonding feature BF1 is substantially coplanar with a surface (e.g., bottom surface) of the etching stop layer ESL1. For example, surfaces (e.g., top surfaces) of the barrier layer (e.g., barrier layer BL2) and the conductive layer (e.g., conductive layer ML2) of the bonding pad BP1 are substantially coplanar with a surface (e.g., top surface) of the second dielectric layer DL2, and a surface (e.g., bottom surface) of the barrier layer (e.g., barrier layer BL1) of the bonding via BV1 is substantially coplanar with a surface (e.g., bottom surface) of the etching stop layer ESL1. In an embodiment in which the etching stop layer ESL1 is omitted, a surface (e.g., bottom surface) of the barrier layer (e.g., barrier layer BL1) of the bonding via BV1 is substantially coplanar with a surface (e.g., bottom surface) of the first dielectric layer DL1.

In some embodiments, the first dielectric layer DL1 and the second dielectric layer DL2 are respectively a single layer. The bonding via BV1 (e.g., first conductive layer ML1) is disposed in the first dielectric layer DL1 and the second dielectric layer DL2. The bonding via BV1 (e.g., first conductive layer ML1) substantially has the first width w1 in the first dielectric layer DL1 and the second dielectric layer DL2, for example. The bonding pad BP1 (e.g., second conductive layer ML2) is disposed in the second dielectric layer DL2, and the bonding pad BP1 (e.g., second conductive layer ML2) has a second width w2 larger than the first width w1 and is disposed over (e.g., in physical contact with) the bonding via BV1 (e.g., first conductive layer ML1). In some embodiments, an interface of the bonding via BV1 and the bonding pad BP1 is higher than an interface of the first dielectric layer DL1 and the second dielectric layer DL2. The bonding pad BP1 may be entirely disposed in the second dielectric layer DL2, and the bonding via BV1 may be partially disposed in the second dielectric layer DL2, the first dielectric layer DL1 and the etching stop layer ESL1. In some embodiments, a central axis CO1 of the bonding via BV1 is substantially overlapped with a central axis CO2 of the bonding pad BP1. That is, the bonding via BV1 and the bonding pad BP1 may be coaxial and thus have coaxial profiles.

In some embodiments, the bonding feature BF1 is disposed over (e.g., in physical contact with) the topmost conductive feature 114 of the interconnect structure 110. For example, the barrier layer BL1 is in direct contact with the topmost conductive feature 114 of the interconnect structure 110. In some embodiments, the first and second dielectric layers DL1 and DL2 aside the bonding feature BF1 are also referred to as dielectric bonding layers, and the bonding feature BF1 and the first and second dielectric layers DL1 and DL2 may be also referred to as a bonding structure or a hybrid bonding structure. In some embodiments, the bonding feature BF1 is in direct contact with the dielectric bonding layers (e.g., first and second dielectric layers DL1 and DL2). However, the disclosure is not limited thereto. In alternative embodiments, an insulating liner is optionally formed between the bonding feature BF1 and the adjacent film layer (e.g., the first dielectric layer DL1 and/or the second dielectric layer DL2) to electrically insulate each bonding feature from the adjacent film layer. For example, an insulating liner is formed between the bonding via BV1 and the first and second dielectric layers DL1 and DL2, and an insulating liner is formed between the bonding pad BP1 and the second dielectric layer DL2. The insulating liner may include silicon oxide or the like.

In some embodiments, conductive pads (not shown) are formed over and electrically connected to the interconnect structure 110 and formed aside the bonding feature. The conductive pads may be aluminum-containing pads. In some embodiments, some of the conductive pads have probe marks on the surfaces thereof. In other words, the integrated circuit is a “known good die”. In alternative embodiments, the conductive pads are free of probe marks.

In some embodiments, an integrated circuit 10 is formed. The integrated circuit 10 may be an application-specific integrated circuit (ASIC) chip, an analog chip, a sensor chip, a wireless and radio frequency chip, a voltage regulator chip or a memory chip, for example.

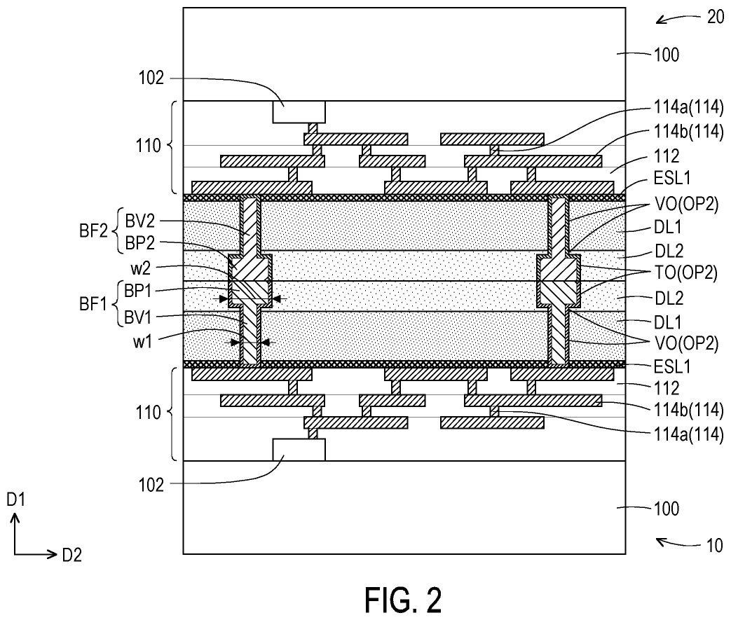

In some embodiments, as shown in FIG. 2, the integrated circuit 10 may be further bonded to another integrated circuit 20. The integrated circuit 10′ may be similar to or different from the integrated circuit 10. The integrated circuit 20 may be an application-specific integrated circuit (ASIC) chip, an analog chip, a sensor chip, a wireless and radio frequency chip, a voltage regulator chip or a memory chip, for example. The integrated circuit 20 may have a size substantially equal to or different from the size of the integrated circuit 10. In some embodiments, the integrated circuit 20 includes a substrate 100, an interconnect structure 110 and a bonding feature BF2. The substrate 100 and the interconnect structure 110 may be formed using similar materials and methods as the substrate 100 and the interconnect structure 110 described above with reference to FIG. 1A, and the description is not repeated herein.

In some embodiments, the bonding feature BF2 may be formed using similar materials and methods as the bonding feature BF1 described above with reference to FIG. 1B to FIG. 1I, and the description is not repeated herein. That is, the bonding feature BF2 may be also formed by using one mask to have coaxial profiles. The bonding feature BF2 may include a bonding pad BP2 and a bonding via BV2. The bonding via BV2 is disposed in the first dielectric layer DL1, the dielectric layer DL2 and the etching stop layer ESL1, and the bonding pad BP2 is disposed in the first dielectric layer DL1 and the dielectric layer DL2, for example. Materials of the first dielectric layer DL1, the dielectric layer DL2 and the etching stop layer ESL1 in the integrated circuit 20 may be respectively the same as or different from materials of the first dielectric layer DL1, the dielectric layer DL2 and the etching stop layer ESL1 in the integrated circuit 10.

In some embodiments, the integrated circuit 20 and the integrated circuit 10 are back-to-face bonded together by a hybrid bonding including a metal-to-metal bonding and a dielectric-to-dielectric bonding. Specifically, the bonding layer (e.g., dielectric layer DL1) of the integrated circuit 20 is bonded to the bonding layer (e.g., dielectric layer DL1) of the integrated circuit 10, and the bonding feature BF2 (e.g., bonding pad BP2) of the integrated circuit 20 is bonded to the bonding feature BF1 (e.g., bonding pad BP1) of the integrated circuit 10. In some embodiments, before the integrated circuit 20 is bonded to and electrically connected to the integrated circuit 10, the bonding feature BF2 and the bonding feature BF1 are aligned by using an optical sensing method. In some embodiments, the width of the bonding feature BF2 of the integrated circuit 20 is substantially the same as the width of the bonding feature BF1 of the integrated circuit 10. However, the disclosure is not limited thereto. In alternative embodiments, the width of the bonding feature BF2 of the integrated circuit 20 is different from the width of the bonding feature BF1 of the integrated circuit 10. In some embodiments, as mentioned above, both bonding features BF1 and BF2 of the integrated circuits 10 and 20 are formed by using the method described above with reference to FIG. 1B to FIG. 1I, and thus during formations of the bonding features BF1 and BF2, the overlay concern is avoided and/or the cost may be lowered. However, the disclosure is not limited thereto. In alternative embodiments, the bonding feature BF2 may be formed by using other methods such as a dual damascene process, multiple single damascene processes, an electroplating process or other suitable process.

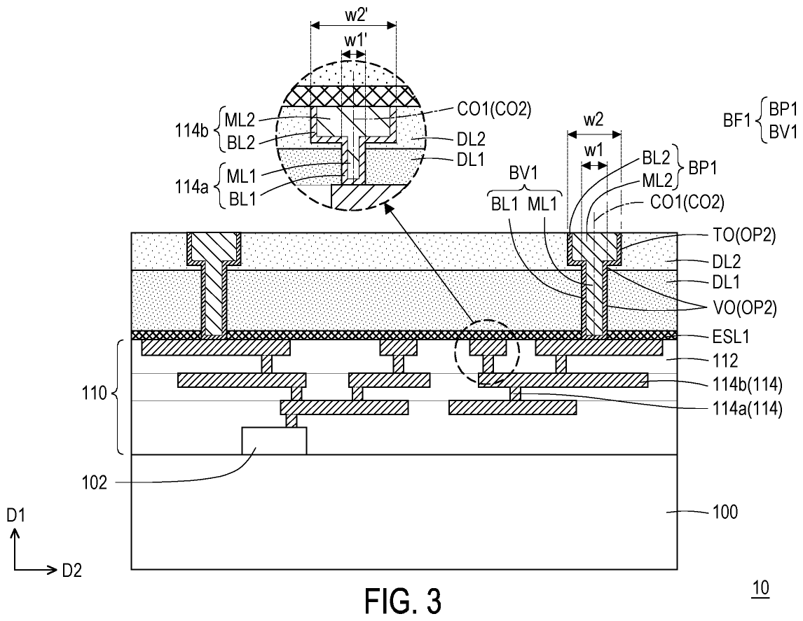

The formation method of the trench opening and the via opening described above with reference to FIG. 1B to FIG. 1H are illustrated for forming the bonding feature. However, the disclosure is not limited. The formation method described above with reference to FIG. 1B to FIG. 1H may be used for forming any suitable structure including continuous trench opening and via opening. The structure in the via opening is also referred to as via portion, and the structure in the trench opening is also referred to as line portion. The via portion may be a bonding via such as bonding via BV1, a conductive via in the interconnect or any conductive structure in the via opening, and the line portion may be a bonding pad such as bonding pad BP1, a conductive line in the interconnect structure or any conductive structure in the trench opening. For example, as shown in FIG. 3, the conductive features 114 include a conductive via 114a in a via opening VO and a conductive line 114b in a trench opening TO. The via opening VO and the trench opening TO may be formed by using the method described above with reference to FIG. 1B to FIG. 1H. The conductive via 114a is disposed in the first dielectric layer DL1, the second dielectric layer DL2 and the etching stop layer ESL1, and the conductive line 114b is disposed in the second dielectric layer DL2, for example. The first dielectric layer DL1 aside the conductive via 114a may be directly disposed on any dielectric layer 112 of the interconnect structure 110 or on the device 102. That is, the conductive via 114a is in direct contact with and electrically connected to the conductive feature 114 or the device 102, for example. The conductive line 114b may be in direct contact with the conductive via 114a. The conductive line 114b and the conductive via 114a are integrated formed, for example. The conductive line 114b has a width w2′ larger than a width w1′ of and the conductive via 114a. In some embodiments, a central axis CO1 of the conductive via 114a is substantially overlapped with a central axis CO2 of the conductive line 114b. That is, the conductive via 114a and the conductive line 114b may be coaxial and thus have coaxial profiles. Materials of the first dielectric layer DL1, the dielectric layer DL2 and the etching stop layer ESL1 aside the conductive features 114 may be respectively the same as or different from the materials of the first dielectric layer DL1, the dielectric layer DL2 and the etching stop layer ESL1 aside the bonding feature BF1.

The structure and formation of the conductive via 114a and the conductive line 114b are similar to that of the bonding via BV1 and the bonding pad BP1. For example, the conductive via 114a and the conductive line 114b respectively include conductive layers ML1, ML2. The conductive layer ML1, ML2 may include tungsten (W), copper (Cu), a copper alloy, aluminum (Al), an aluminum alloy or a combination thereof. The conductive layer ML1 is continuously disposed in the first dielectric layer DL1, the second dielectric layer DL2 and the etching stop layer ESL1, for example. The conductive layer ML1 and the conductive layer ML2 may be integrally formed. That is, no interface exists between the conductive layer ML1 and the conductive layer ML2. In some embodiments, a barrier layer BL1, BL2 is formed between the conductive layer ML1, ML2 and the dielectric layers DL1 and DL2 and the etching stop layer ESL1 to prevent the material of the conductive feature 114 from migrating to the underlying device 102. The barrier layer BL1, BL2 may include Ta, TaN, Ti, TiN, CoW or a combination thereof. The barrier layer BL1 is continuously disposed in the first dielectric layer DL1, the second dielectric layer DL2 and the etching stop layer ESL1, for example. The barrier layer BL1 and the barrier layer BL2 may be integrally formed. That is, no interface exists between the barrier layer BL1 and the barrier layer BL2. A seed layer (not shown) may be optionally formed between each conductive feature 114 and the barrier layer BL1, BL2. The seed layer may include Cu, Ag or the like. In FIG. 3, both bonding feature BF1 and conductive features 114 are formed by the formation method described above with reference to FIG. 1B to FIG. 1H. However, the disclosure is not limited thereto. In alternative embodiments, one of the bonding features BF1 and the conductive features 114 may be formed by using other methods such as a dual damascene process, multiple single damascene processes, an electroplating process or other suitable process.

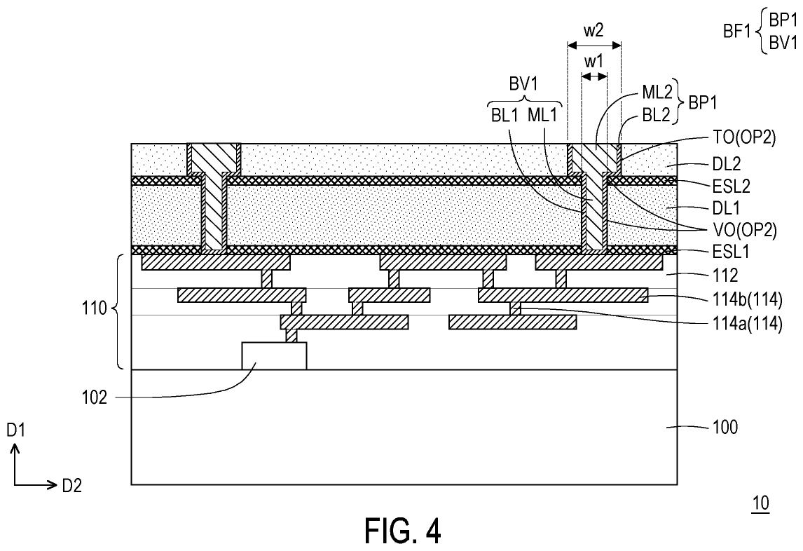

In the above embodiments, the first dielectric layer is in direct contact with the second dielectric layer. However, the disclosure is not limited thereto. In alternative embodiments, as shown in FIG. 4, an etch stop layer ESL2 is further formed between the first and second dielectric layers DL1 and DL2. In such embodiments, the trench opening TO is disposed in an entirety of the second dielectric layer DL2 and the via opening VO is disposed in the etching stop layer ESL2, the first dielectric layer DL1 and the etching stop layer ESL1. Accordingly, the bonding pad BP1 is disposed in an entirety of the second dielectric layer DL2, and the bonding via BV1 is disposed in the etching stop layer ESL2, the first dielectric layer DL1 and the etching stop layer ESL1.

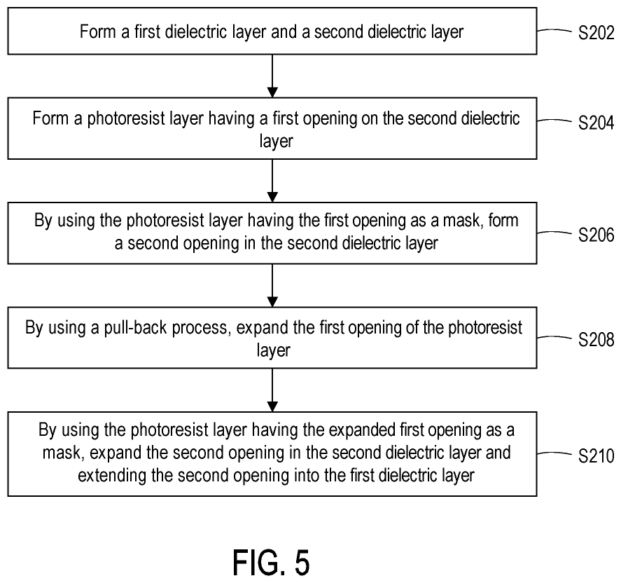

FIG. 5 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S202, a first dielectric layer and a second dielectric layer are formed. FIG. 1B illustrate a view corresponding to some embodiments of act S202.

At act S204, a photoresist layer having a first opening is formed on the second dielectric layer. FIG. 1C illustrates a view corresponding to some embodiments of act S204.

At act S206, by using the photoresist layer having the first opening as a mask, a second opening is formed in the second dielectric layer. FIG. 1D illustrates a view corresponding to some embodiments of act S206.

At act S208, by using a pull-back process, the first opening of the photoresist layer is expanded. FIG. 1E illustrates a view corresponding to some embodiments of act S208.

At act S210, by using the photoresist layer having the expanded first opening as a mask, the second opening is expanded in the second dielectric layer and extended into the first dielectric layer. FIG. 1F illustrates a view corresponding to some embodiments of act S210.

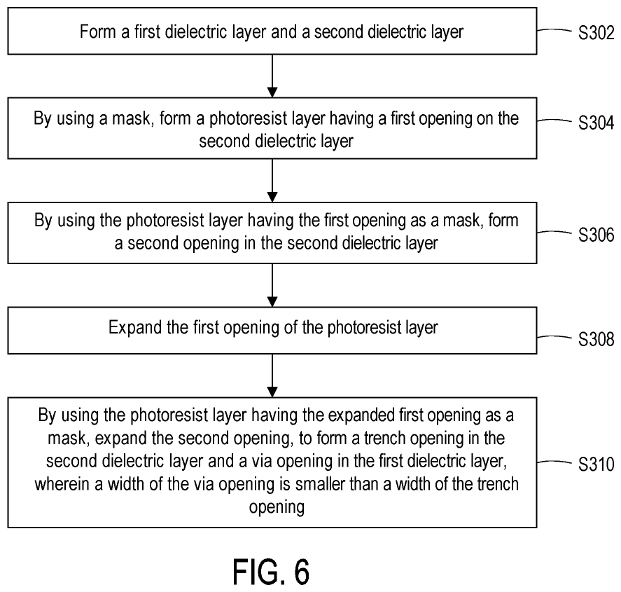

FIG. 6 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S302, a first dielectric layer and a second dielectric layer are formed. FIG. 1B illustrate a view corresponding to some embodiments of act S302.

At act S304, by using a mask, a photoresist layer having a first opening is formed on the second dielectric layer. FIG. 1C illustrates a view corresponding to some embodiments of act S304.

At act S306, by using the photoresist layer having the first opening as a mask, a second opening is formed in the second dielectric layer. FIG. 1D illustrates a view corresponding to some embodiments of act S306.

At act S308, the first opening of the photoresist layer is expanded. FIG. 1E illustrates a view corresponding to some embodiments of act S308.

At act S310, by using the photoresist layer having the expanded first opening as a mask, the second opening is expanded, to form a trench opening in the second dielectric layer and a via opening in the first dielectric layer, wherein a width of the via opening is smaller than a width of the trench opening. FIG. 1F illustrates a view corresponding to some embodiments of act S310.

According to some embodiments, a semiconductor device includes a first dielectric layer, a second dielectric layer, a first conductive layer and a second conductive layer. The second dielectric layer is disposed on the first dielectric layer. The first dielectric layer and the second dielectric layer are respectively a single layer. The first conductive layer is disposed in the first dielectric layer and the second dielectric layer. The first conductive layer substantially has a first width in the first dielectric layer and the second dielectric layer. The second conductive layer is disposed in the second dielectric layer. The second conductive layer has a second width larger than the first width and is disposed over the first conductive layer.

According to some embodiments, a method of forming a semiconductor device includes following steps. A first dielectric layer and a second dielectric layer are formed. A photoresist layer having a first opening is formed on the second dielectric layer. By using the photoresist layer having the first opening as a mask, a second opening is formed in the second dielectric layer. By using a pull-back process, the first opening of the photoresist layer is expanded. By using the photoresist layer having the expanded first opening as a mask, the second opening is expanded in the second dielectric layer and extended into the first dielectric layer.

According to some embodiments, a method of forming a semiconductor device includes following steps. A first dielectric layer and a second dielectric layer are formed. By using a mask, a photoresist layer having a first opening is formed on the second dielectric layer. By using the photoresist layer having the first opening as a mask, a second opening is formed in the second dielectric layer. The first opening of the photoresist layer is expanded. By using the photoresist layer having the expanded first opening as a mask, the second opening is expanded, to form a trench opening in the second dielectric layer and a via opening in the first dielectric layer, wherein a width of the via opening is smaller than a width of the trench opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first dielectric layer;
a second dielectric layer on the first dielectric layer, wherein the first dielectric layer and the second dielectric layer are respectively a single layer;
a first conductive layer in the first dielectric layer and the second dielectric layer, wherein the first conductive layer substantially has a first width in the first dielectric layer and the second dielectric layer; and
a second conductive layer in the second dielectric layer, wherein the second conductive layer has a second width larger than the first width and is disposed over the first conductive layer.

2. The semiconductor device of claim 1, wherein a material of the first dielectric layer is different from a material of the second dielectric layer.

3. The semiconductor device of claim 1, wherein the first conductive layer is continuously disposed in the first dielectric layer and the second dielectric layer.

4. The semiconductor device of claim 1, wherein no interface exists between the first conductive layer and the second conductive layer.

5. The semiconductor device of claim 1, further comprising an etching stop layer beneath the first dielectric layer, wherein the first conductive layer is further disposed in the etching stop layer.

6. A method of forming a semiconductor device, comprising:
forming a first dielectric layer and a second dielectric layer;
forming a photoresist layer having a first opening on the second dielectric layer;
by using the photoresist layer having the first opening as a mask, forming a second opening in the second dielectric layer;
by using a pull-back process, expanding the first opening of the photoresist layer; and
by using the photoresist layer having the expanded first opening as a mask, expanding the second opening in the second dielectric layer and extending the second opening into the first dielectric layer.

7. The method of claim 6, wherein expanding the first opening of the photoresist layer is performed after forming the second opening in the second dielectric layer.

8. The method of claim 6, wherein expanding the second opening in the second dielectric layer and extending the second opening into the first dielectric layer comprises:
expanding the second opening in the second dielectric layer and extending the second opening into a first depth of the first dielectric layer; and
extending the second opening to penetrate through the first dielectric layer.

9. The method of claim 8, wherein by expanding the second opening in the second dielectric layer and extending the second opening into the first depth of the first dielectric layer, the second opening has a first width in the first dielectric layer and the second dielectric layer and a second width larger than the first width in the second dielectric layer.

10. The method of claim 9, wherein by extending the second opening to penetrating through the first dielectric layer, the second opening has the first width throughout the first dielectric layer.

11. The method of claim 9, wherein extending the second opening to penetrate through the first dielectric layer comprises extending a portion of the second opening having the second width in the second dielectric layer and extending a portion of the second opening having the first width in the first dielectric layer.

12. The method of claim 6, further comprising removing the photoresist layer by a removal process.

13. The method of claim 12, wherein the second opening is further extending in the second dielectric layer after the removal process.

14. The method of claim 12, further comprising forming an etching stop layer beneath the first dielectric layer, wherein the second opening is further extending into the etching stop layer after the removal process.

15. A method of forming a semiconductor device, comprising:
forming a first dielectric layer and a second dielectric layer;
by using a mask, forming a photoresist layer having a first opening on the second dielectric layer;
by using the photoresist layer having the first opening as a mask, forming a second opening in the second dielectric layer;
expanding the first opening of the photoresist layer; and
by using the photoresist layer having the expanded first opening as a mask, expanding the second opening, to form a trench opening in the second dielectric layer and a via opening in the first dielectric layer, wherein a width of the via opening is smaller than a width of the trench opening.

16. The method of claim 15, wherein the via opening is further formed in the second dielectric layer.

17. The method of claim 15, further comprising forming an etching stop layer beneath the first dielectric layer, wherein the via opening is further formed in the etching stop layer.

18. The method of claim 15, wherein the width of the via opening is substantially the same as the first opening.

19. The method of claim 15, wherein the via opening is substantially coaxial with the trench opening.

20. The method of claim 15, further comprising forming a conductive layer in the trench opening and the via opening.
